(19) United States
(12) Patent Application Publication
(10) Pub. No.: US 2016/0342912 A1
(43) Pub. Date: Nov. 24, 2016

(54) PRODUCTION SITE SIMULATION

(71) Applicant: HEWLETT-PACKARD DEVELOPMENT COMPANY, L.P., Houston, TX (US)

(72) Inventors: Sunil Kothari, Palo Alto, CA (US); Jun Zeng, Palo Alto, CA (US); Gary J. Dispoto, Palo Alto, CA (US)

(21) Appl. No.: 15/114,389

(22) PCT Filed: Jan. 30, 2014
(86) PCT No.: PCT/US2014/013921

§ 371 Date: Jul. 26, 2016

(51) Int. Cl. G06Q 10/06; G06F 17/50

(52) U.S. Cl. CPC G06Q 10/0637; G06Q 10/067; G06F 17/5009

(57) ABSTRACT

A user interface (71) to a computing device (90) receives geographic locations for a plurality of production sites. A socio-economic relevancy analyzer (72) determines relevancy of socio-economic information for the plurality of production sites. A socio-economic events analyzer (73) performs analysis of potential effects of the socio-economic information obtained by the socio-economic event relevancy analyzer (72) as pertains to the plurality of production sites. A simulator (74) simulates production of each of the production sites. The simulator (74) utilizes analysis of potential effects of the socio-economic information performed by the socio-economic events analyzer (73).

### BACKGROUND

Production sites provide goods and services. Production sites can for instance be custom manufacturers of goods, service providers, or both a manufacturer of goods and a service provider is in the case of a provider of 3-D printing. For example, print service providers (PSPs) are businesses and other entities that offer print and print-related services to customers. Printing jobs are typically received in digital form, either through physical media or transferred electronically over a network such as the Internet. The PSPs then perform traditional print services such printing varied materials, such as photographs and brochures, course materials and books, as well as advertisements, product packaging, and other types of print materials. A PSP facility also typically provides on-demand production of photo books and so on.

Large PSPs can have multiple sites either in a single country or spread out over many different countries. Also, several PSPs may collaborate together to fill a job through, for example, out sourcing arrangements. These PSPs can be in a same area or geographically dispersed.

### BRIEF DESCRIPTION OF DRAWINGS

FIG. 1 is a simplified block diagram illustrating an example of components of socio-economic systems in accordance with an implementation.

FIG. 2 is a simplified block diagram of an example of a system that guides service fulfillment for multiple production sites in accordance with an implementation.

FIG. 3 is a simplified flowchart illustrating an example of an effect of one variable on values of other variables in accordance with an implementation.

FIG. 4 is a simplified flowchart describing production site simulation in accordance with an implementation.

FIG. 5 is a simplified block diagram of a computing system used for production site simulation in accordance with an implementation.

FIG. 6 is a simplified flowchart describing an example of a system that guides service fulfillment for multiple print service production sites in accordance with an implementation.

### DETAILED DESCRIPTION

In order to predict, support and optimize performance of production sites in scattered geographic locations, simulations can be used. To improve effectiveness, the simulations can take into account socio-economic information based on the geographic locations of the production sites. The socio-economic information is for events and factors that are outside the production sites. The socio-economic information provides a context for what is happening inside the production sites. When production sites are geographically apart, for example located in different countries, taking into account the socio-economic information allows for better strategic planning decisions.

Use of socio-economic information for events and factors that are outside the production sites helps account for the variability that exists outside-the-four-walls of a production site and facilitates analysis of long term effects of that variability on the demand and the supply side of production sites. This allows for a more accurate and realistic picture of the present and the future. When a user varies values for parameters within the socio-economic information, this facilitates planning and forecasting.

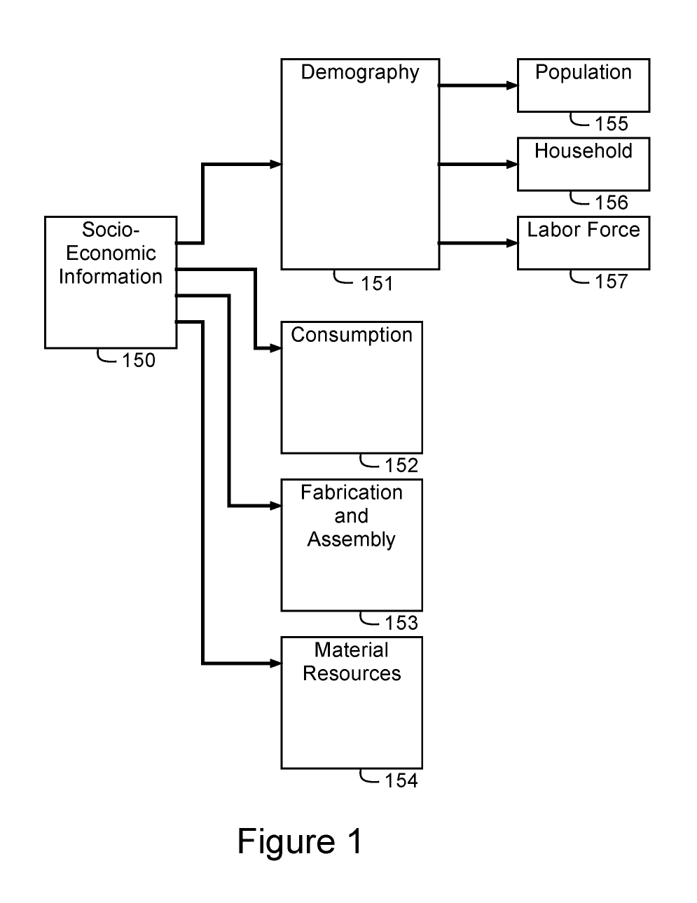

For example, FIG. 1 shows socio-economic information 150 for the geographic location of a single production site being composed of four components. Specifically, socio-economic information 150 is shown to be composed of a demography component 151, a consumption component 152, a fabrication and assembly component 153 and a material resources component 154.

Demography component 151 includes demographic information about composition of the population in the geographic area near the production site. This is relevant to the production site as the population is the source of much of the current and potential workforce. For example, the demographic information may include supply of migrant workers, availability, reliability and access to transportation to the production site.

FIG. 1 shows three categories of demographic information: a population category 155, a household category 156 and a labor force category 157. Population category 155 includes, for example, information about age and gender of the population. Household category 156 includes, for example, information about households (e.g., families) including size of the household and age of members within the households. Labor force category 156 includes information such as information about labor force size, and age and gender of those within the labor force. Demographic information contained within demography component 151 encompasses decisions and events made with respect to fertility, migration, family formulation, labor force participation and so on.

Consumption component 152 includes information that impacts the consumption of goods and services: This can include stocks of goods as well as infrastructure that pertains to provision of goods and services. For example, consumption component 152 can include, for example, availability of stores, dwellings, household durable goods, household consumables, available health services, schools, transportation, business offices and so on in the geographic area near the production site. When goods and service produced by the production site are to be exported, consumption component 152 can also include relevant factors relating to export of the goods and services to a targeted export region.

Fabrication and assembly component 153 includes information pertaining to processes that transform materials and primary energy into finished goods that are needed for consumption and material resources. Sub-components of fabrication and assembly component 153 can include, information pertaining to regional manufacturing capacity, composition of goods, operation processes and so on.

Material Resources component 154 includes material resources information about availability of materials and energy from renewable and non-renewable resources available near the production site. When raw material are imported, material resources component can include information about the sources including shipping availability, reliability and cost. Material Resources component 154 can include, for example, information about primary energy sources, minerals, forest products, agriculture, fish and wildlife harvesting and so on.

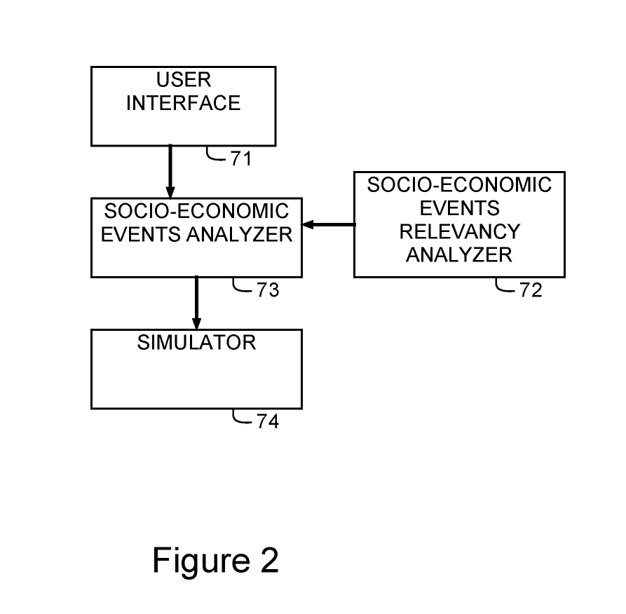

FIG. 2 is a simplified block diagram of a system, implemented using one or more computer systems, that performs simulations that provide guidance towards optimal composite service fulfillment for multiple production sites by taking into account socio-economic information based on geographical location of the production sites. For example, the system generates audit data for demand “what-if” or resource “what-if” scenarios. This allows for analysis of service levels, current demand trends, future capacity enhancements and future demand enhancements. In addition, this type of scenario planning simulation can be applied to analyze the sensitivity to factors external to the production system, for example, how possible labor law changes affect the availability and cost of the labor force. The simulations also can allow for the evaluation of the effect of service agreements between production sites. Simulations can also evaluate changes to a production site. For example, a simulation can evaluate the effect of making capital investments at one production site verses opening an entirely new production site in a geographically different location. A simulation also can evaluate the effect of service agreements for current and future sourcing partners.

A user interface 71 to a computing device receives information from a user. The information can include, for example, geographic location of production sites, current and predicted production requirements, user selected parameters and so on. For example, user interface 71 captures user input from an interview requesting information about the production sites. For example, an interview can be conducted with a factory manager for each production site. Alternatively, or in addition, information already created and stored information such as operating policies, equipment details, product types, demands, and so on can be accessed.

The captured information is used, for example, to run simulation experiments. Results from the simulation experiments can be synthesized and analyzed to generate recommendations for the production sites.

A socio-economic event relevancy analyzer 72 examines relevance of socio-economic information pertaining to the geographic locations of the production sites. For example, socio-economic events are provided to socio-economic event relevancy analyzer 72 by a data mining engine that crawls the internet for socio-economic information based on the geographic locations of the production sites. Alternatively, or in addition, socio-economic events are provided to socio-economic event relevancy analyzer 72 by an interface that can be utilized by a user to input potentially relevant socio-economic information. The information searched typically includes all the components of socio-economic information 150.

In order to examine the relevance of socio-economic information, socio-economic event relevancy analyzer 72 accesses a lexicon of interesting socio-economic words such as migration, port, rail route etc. This lexicon can be either populated manually or updated by software based on analysis of past socio-economic events. For each feed of socio-economic information, socio-economic event relevancy analyzer 72 parses the feed of socio-economic information and divides the feed into tokens. Stemming is performed to find the root of words. When this is complete, semantic classes are assigned to the result. The semantic classes determine, what, where, when and scope.

For example, consider a feed of the following socio-economic information: “US Dept of Commerce today announced plans to increase worker visa program by up to 20% to allow migration for young people from 2009-2019.” As a result of parsing, tokenization, stemming and assignation to semantic classes, the feed is dissected into the following: TERMS—20% increase in migration; WHERE—US; WHEN—2009-2019; SOURCE—Bloomberg; SCOPE—Countrywide (since US is mentioned and no state is mentioned).

Each semantic category is weighted with respect to scope, matching with the lexicon, and reputation of the source. Each weighted category is then added together to determine a final score. Feeds of socio-economic information that do not meet a certain threshold score are discarded as not relevant. Non-discarded feeds are passed on to a socio-economic events analyzer 73.

Socio-economic events analyzer 73 performs analysis of potential effects of the socio-economic information determined to be relevant by the socio-economic event relevancy analyzer 72. Analysis of the socio-economic information allows exploration of future states based on the aggregation of socio-economic information pertaining to elemental units such as a household, an individual or a firm. Use of such socio-economic information allows deeper and richer analysis. For example, socio-economic events analyzer 73 allows variation of parameters and parameter values within a specified range that represent socio-economic events and factors. This variance allows “what if” analysis to allow effective evaluation forecasting of how various socio-economic events and factors may effect operation of production sites or potential production sites. This allowance of variation is especially helpful for areas where socio-economic information is incomplete or uncertain.

A simulator 74 simulates demand for goods and/or services and production at each of the production sites taking into account the socio-economic information. The simulator utilizes the analysis performed by socio-economic events analyzer 73. Socio-economic events analyzer 73 sets up the appropriate parameters for demand and for each production site. Simulator 74 can be implemented in various ways in order to accomplish specific purposes. For example, the simulator includes a service engagement broker that analyzes objectives, current state and cost in order to efficiently allocate production assignments to each production site. For example, the simulator includes a demand simulator that estimates demands for goods or services produced by the production site based on the socio-economic information. For example, the simulator includes an enhancer engine that provides optimization information for service level agreements between production sites and outsourcing partners.

When socio-economic events analyzer 73 performs analysis of potential effects of the socio-economic information, socio-economic events analyzer 73 propagates effects of events across socio-economic components.

For example, migration will affect the demography in the sense that it will change the household distribution and populations. A direct result of migration will be the available labor supply will increase assuming at least a percentage of migrants are eligible to work. An indirect result will be that the new arrivals will affect consumption in the region. For example, they will use transportation and consume goods. They require dwelling to live in. And so on.

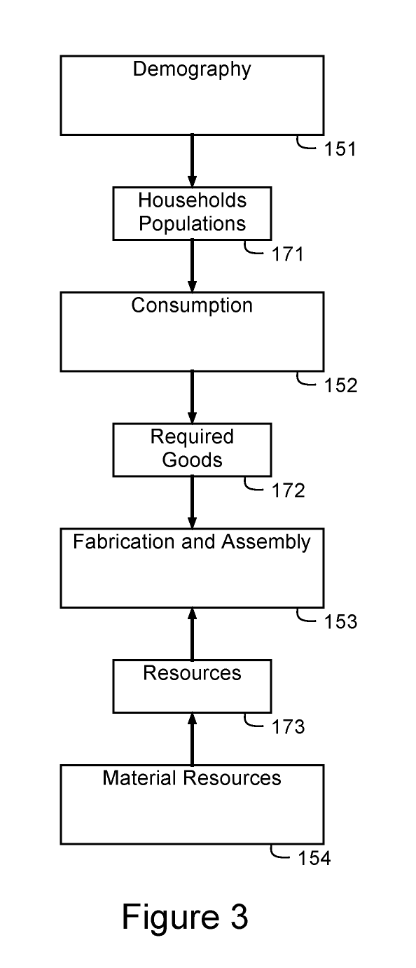

This is illustrated by FIG. 3, which illustrates that the values used for one socio-economic parameter within one component of a socio economic model can impact values of other socio-economic parameters used in other components of a socio economic model. In FIG. 3, demographic parameters 171 for household and populations, will impact consumption component 152. Required goods 172 for consumption will impact needs predicted in fabrication and assembly component 153. Likewise, changes in available renewable and non-renewable resources 173 will impact materials and primary energy available to be turned into finished products within fabrication and assembly component 153.

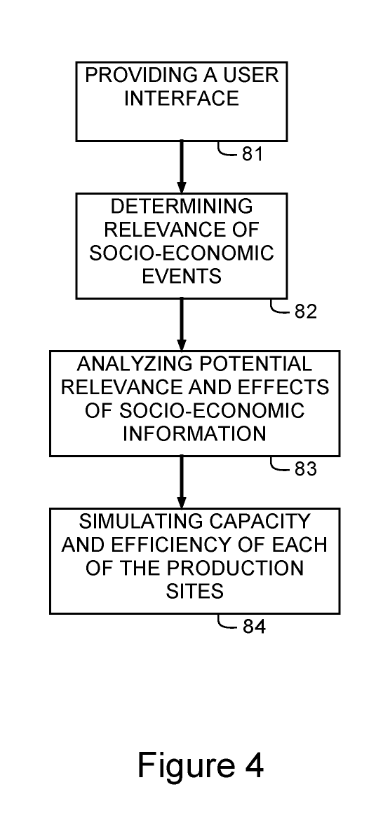

FIG. 4 is a simplified flowchart describing production site simulation. In a block 81, a user interface is provided by a computing device. The user interface receives information pertaining to a plurality of production sites. In a block 82, relevance of socio-economic information pertaining to the plurality of production sites is determined. The socio-economic information is for events and factors that are outside the production sites.

In a block 83, potential relevance and effects of the socio-economic information as pertains to the plurality of production sites are analyzed. In a block 84, capacity and efficiency of each of the production sites are simulated. The simulation utilizes the analysis of potential relevance and effects of the socio-economic information.

The process described in FIG. 4 is implemented by a computer device. For example the computing device is a computing system of one or more computers. For example, computer in the computing system can be in communication with each other by a local or wide area network.

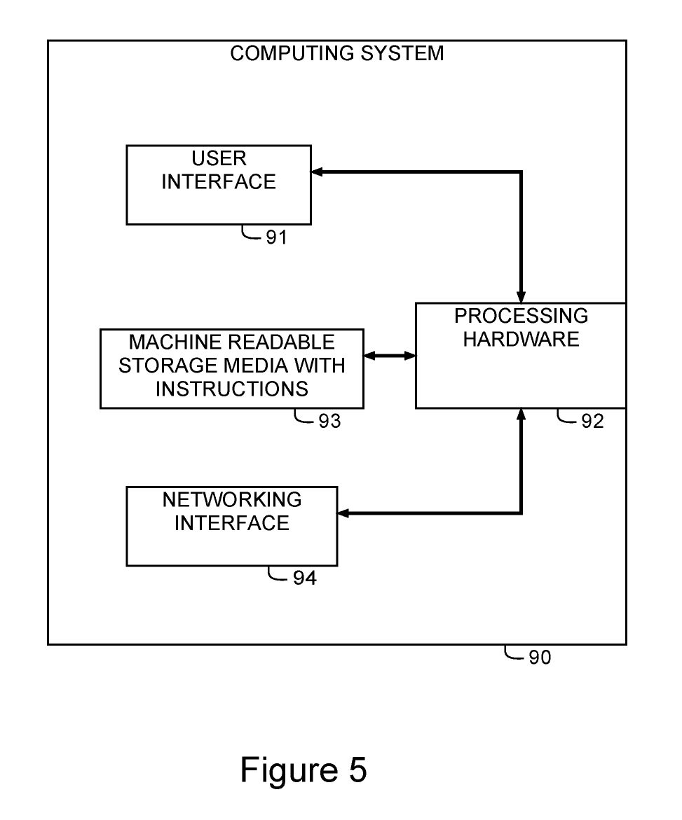

FIG. 5 shows a simplified computer system 90 that can implement the process described in FIG. 4. FIG. 5 shows a user interface 91 and a networking interface 94 connected to processing hardware 92. Processing hardware 92 accesses machine readable storage media 93 to access computer instructions that when run, execute the process described in FIG. 4. Processing hardware 92 and machine readable storage media 93 is representative of hardware and software that can located within a single computer or distributed across many computers located locally or across a wide area.

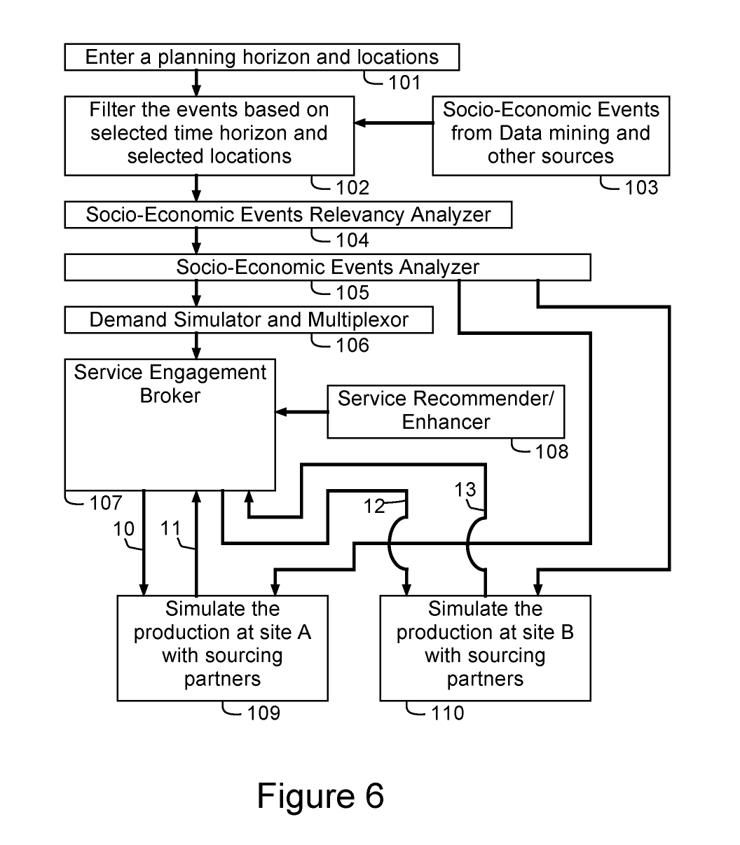

One example of multiple production sites is a geographically distributed network of print server providers (PSPs). FIG. 6 is a simplified flowchart describing a system that guides service fulfillment for multiple print service production sites.

In a block 101, by use of a computer interface, a user enters a selected planning horizon and locations. The planning horizon indicates the time over which guidance will be provided. The locations indicate geographic locations of PSPs. The computer interface can also be used to capture details about the production site, for example, by conducting an interview with a factory manager.

A block 103 represents input of socio-economic information such as events and other factors. This information is gathered through data mining from the internet, or from other sources. For example, a user may manually enter information about pertinent events that have already taken place or might potentially take place. The events are considered pertinent if the events could impact guidance for decisions made pertaining to the print service providers. For example, both socio-economic and the geographic factors that affect the supply and the demand side of a commercial print factory might be considered pertinent. On the demand side, the distribution of products, market share, product variety, percent revenue by product, and when they are requested are affected by the various socio-economic factors such as demands for photo books peak on important occasions such as marriage, graduation etc. Events such as marriages are based on a number of factors such as demographic profile, birth rate, death rate, etc. On the supply side, the availability of labor, raw materials, ink etc. is affected by government regulations, tariff structure, and environmental factors.

A block 102 filters the events provided by block 103 based on the time horizon and the locations selected in block 101. Events not deemed pertinent to the production sites can be discarded or archived.

Block 104 represents operation of a socio-economic events relevancy analyzer on the filtered events. The relevancy analyzer analyzes socio-economic events provided by block 102 to determine their relevancy to the production sites.

Block 105 represents operation of a socio-economic events analyzer on the filtered events. The socio-economic events analyzer takes into account how values of the control variables and other socio-economic information impact propagating/estimating through the components of socio-economic information (as illustrated in FIG. 3) during the course of the planned horizon. In addition, parameters for production sites and their sourcing partners are set, for example, based on input from a user or an overseeing simulation program. The impact of the events are analyzed and respective simulation control variables are set up. The control variables can be modified to determine how changing scenarios and assumptions impact the production sites.

Block 106 represents a demand simulator and multiplexor that estimates demands for goods or services based on the socio-economic information. A demand-fulfillment model determines how the demands are met by distributing assignments to the production sites. For example, demand for printed products at various demand sites is estimated based on the socio-economic information. The demand simulator and multiplexor allows adjustment of how the demand will be met by a combination of output from the production sites. For example, a simulation could be run where a single production site satisfies the demands from two socio-economically diverse locations/regions. Another simulation could be run where the demands from two socio-economically diverse locations/regions are met from two production sites, and to facilitate this, a production site is located geographically close to each socio-economically diverse location. These simulations could be evaluated to determine economic feasibility and advantages.

Block 107 represents operation of a service engagement broker. The service engagement broker includes, for example, a constrained combinatory optimization engine. The constrained combinatory optimization engine analyzes objectives, current state and cost to have tasks performed within a production site or sent to an outsourcing partner for the task. The costs include, for example cost to route jobs to individual sites based on several parameters. These parameters can include production site capacity, work in progress, profitability, required lead time and so on. Information from service engagement broker work informs selection of which production sites and outsourcing partners can most efficiently fulfill particular production jobs.

A service agreement recommender and enhancer block 108 represents operation of a service recommender and enhancer that provides optimization information for support agreements between production sites and outsourcing providers for the production sites. For example, the service agreement recommender and enhancer provides automated service level agreement (SLA) formalization, validation and optimization solutions that optimize the interests of all parties involved within the bounds specified. In addition, service agreement recommender and enhancer block 108 provides recommendations for possible SLA enhancements with quantitative measures against specified objectives. Such information is useful to aid human-involved negotiations especially when trade-offs among multiple parties are necessary.

The SLAs can be optimized based on outsourced tasks. For example, a single outsource partner for a PSP may provide two services, such as printing and cutting. The service recommender and enhancer may recommendations based on each task separately. For example, it may be determined that it is most economical for the PSP to engage the single outsource partner for printing but use another outsource partner for cutting services or perform cutting services within the PSP.

In a block 109, production at a site A with sourcing partners is simulated. The simulation utilizes simulated socio-economic events and effects from block 105. In addition, the simulation utilizes an order stream for site A, represented by an arrow 10, and provided by service engagement broker block 107. To generate the order stream, service engagement broker block 107 utilizes input from service recommender and enhancer block 108 and information from site A, represented by an arrow 11. For example, the information represented by arrow 11 includes work in progress information and utilization rates of resources within site A.

In a block 110, production at site B with sourcing partners is simulated. The simulation utilizes simulated socio-economic events and effects from block 105. In addition, the simulation utilizes an order stream for site A, represented by an arrow 12, and provided by service engagement broker block 107. To generate the order stream, service engagement broker block 107 utilizes input from service recommender and enhancer block 108 and information from site B, represented by an arrow 13. For example, the information represented by arrow 13 includes work in progress information and utilization rates of resources within site B.

Site A and site B are representative of any number of multiple production sites. These production sites can include outsourcing partners.

Socio economic events analyzer 105 can be modeled using expressive frameworks such as the Socio-Economic Resource Framework (SERF) to model socio-economic factors. See for example, R. B. Hoffman and B. C. Mcinnis, “The Evolution of Socio-Economic Modeling in Canada”, In Special Issue Forecasting Social Change in Canada. Vol. 33, Issue 4, Pages 311-323, July 1998; F. D. Gault, K. E. Hamilton, R. B. Hoffman, and B. C. McInnis, “The Design Approach to Socio-economic Modeling”, Futures, February 1987. Statistics Canada, “The Socio-Economic Resource Framework”, SERF, Version II Reference Manual, 1987.

The disclosed subject matter may be implemented in other specific forms without departing from the spirit or characteristics thereof. Accordingly, the present disclosure is intended to be illustrative, but not limiting, of the scope of the following claims.

We claim:

1. A system comprising:
a user interface (71) to at least one computing device (90) that receives information about a plurality of production sites;
a socio-economic relevancy analyzer (72), implemented by the at least one computing device (90), that determines relevancy of socio-economic information for the plurality of production sites, the socio-economic information being for events and factors that are outside the production sites;
a socio-economic events analyzer (73), implemented by the at least one computing device (90), that performs analysis of potential effects of the socio-economic information from the socio-economic event relevancy analyzer (72) as pertains to the plurality of production sites; and,
a simulator (74), implemented by the at least one computing device (90), that utilizes analysis of the effects of the socio-economic information performed by the socio-economic events analyzer (73) when running performance simulations for the production sites within the plurality of production sites.

2. A system as in claim 1 wherein the socio-economic information includes demographic information about potential labor force for each production site in the plurality of production sites.

3. A system as in claim 1 wherein the socio-economic information includes consumption information about infrastructure and stocks of goods pertaining to each production site in the plurality of production sites.

4. A system as in claim 1 wherein the socio-economic information includes material resources information about availability of materials and energy from renewable and non-renewable resources pertaining to each production site in the plurality of production sites.

5. A system as in claim 1 wherein the socio-economic events analyzer (73) propagates effects of events across socio-economic components.

6. A system as in claim 1 wherein each production site in the plurality of production sites is a print service provider.

7. A system as in claim 1 wherein the simulator (74) includes service engagement broker that analyzes objectives, current state and cost to engage each production site in the plurality of production sites.

8. A system as in claim 1 wherein the simulator (74) includes a demand simulator (74) that estimates demands for goods or services based on the socio-economic information.

9. A system as in claim 1 wherein the simulator (74) includes a service agreement enhancer that provides optimization information for support agreements between production sites in the plurality of production sites.

10. A method comprising:
providing, by a computing device (90), a user interface (71) that receives information pertaining to a plurality of production sites;
determining, by the computing device (90), relevance of socio-economic information pertaining to the plurality of production sites, the socio-economic information being for events and factors that are outside the production sites;
analyzing, by the computing device (90), potential relevance and effects of the socio-economic information as pertains to the plurality of production sites; and,
simulating, by the computing device (90), capacity and efficiency of each of the production sites, the simulation utilizing the analysis of potential relevance and effects of the socio-economic information.

11. A method as in claim 10 wherein the socio-economic information includes at least one of the following:
demographic information about people living in geographic areas near each production site in the plurality of production sites;
consumption information about infrastructure and stocks of goods near each production site in the plurality of production sites; and,
material resources information about availability of materials and energy from renewable and non-renewable resources near each production site in the plurality of production sites.

12. A method as in claim 10 wherein simulating
propagating effects of events across socio-economic components.

13. A method as in claim 10 wherein simulating includes:
analyzing objectives, current state and cost to engage each production site in the plurality of production sites.

14. A method as in claim 10 wherein simulating includes:
providing optimization information for service level agreements between production sites in the plurality of production sites and outsourcing partners.

15. A computer program for instructing a computer to perform the method of:
gathering socio-economic information pertaining to a plurality of production sites, the socio-economic information being for events and factors that are outside the production sites;
filtering the socio-economic information based on relevance to operation of the plurality of production sites to produce filtered socio-economic information;
analyzing the filtered socio-economic information to determine effect on operation of the plurality of production sites; and,
simulating capacity and efficiency of each of the production sites, the simulation utilizing the analysis of the filtered socio-economic information.
